(19) United States
(12) Patent Application Publication
(10) Pub. No.: US 2025/0311454 A1
(43) Pub. Date: Oct. 2, 2025

(54) 3D Light Field Detector, Sensor and Methods of Fabrication Thereof

(71) Applicant: National University of Singapore, Singapore (SG)

(72) Inventors: Xiaogang Liu, Singapore (SG); Luying Yi, Singapore (SG); Bo Hou, Singapore (SG)

(21) Appl. No.: 18/866,822

(22) PCT Filed: May 24, 2023
(86) PCT No.: PCT/SG2023/050361

§ 371 Date: Nov. 18, 2024

(30) Foreign Application Priority Data
May 27, 2022 (SG) 10202250025F

(51) Int. Cl. H10F 39/15; H04N 23/90; H04N 23/957; H10F 39/00; H10F 77/14; H10F 77/162

(52) U.S. Cl. CPC H10F 39/156; H04N 23/90; H04N 23/957; H10F 39/011; H10F 77/1433; H10F 77/1625

(57) ABSTRACT

The present disclosure concerns a light field detector for converting a vector of an 5 electromagnetic radiation into a chromatic output, comprising at least one azimuth detector on a transparent substrate and the at least one azimuth detector comprising at least two luminescent nanocrystal pixels having different emission wavelengths relative to each other. The present disclosure also concerns a light field sensor comprising the light field detector thereof and methods of fabricating the light field 10 detector.

### TECHNICAL FIELD

The present invention relates, in general terms, to a 3D light field detector, sensor and methods of fabrication thereof.

### BACKGROUND

Although advances in materials and semiconductor processes have revolutionized design and fabrication of micro/nano photodetectors, the pixels of most sensors detect only the intensity of electromagnetic waves. As a result, all phase information of the objects and diffracted light waves is lost. While intensity information alone is sufficient for conventional applications such as two-dimensional (2D) photography and microscopic imaging, this limitation hinders three-dimensional (3D) or even four-dimensional (4D) imaging applications, such as high-resolution phase-contrast imaging, light detection and ranging (LIDAR), autonomous vehicles, virtual reality, and space exploration. Light fields that characterize phase information are usually measured by combining bulky optical elements such as microlens arrays or photonic crystals with pixelated photodiodes. Nevertheless, integration of these elements into complementary metal-oxide-semiconductor architectures is costly and complex. Optical resonances in subwavelength semiconductor structures offer the possibility of developing angle sensitive structures by manipulating light-matter interactions. However, most of them are wavelength- or polarization-dependent and require high refractive index materials. In addition, detection and control of light field vector are currently limited to the ultraviolet and visible wavelength ranges. While a few sensor systems based on Shack-Hartmann or Hartmann structures can be used in the extreme ultraviolet range, field measurements of hard X-rays and gamma-rays remain a formidable challenge because these high energy beams cannot be focused by conventional mirrors and microlenses.

It would be desirable to overcome or ameliorate at least one of the above-described problems.

### SUMMARY

Disclosed is a light field detector for converting a vector of an electromagnetic radiation into a chromatic output, comprising at least one azimuth detector on a transparent substrate and the at least one azimuth detector comprising at least two luminescent nanocrystal pixels having different emission wavelengths relative to each other.

The light field detector may comprise at least two said azimuth detectors oriented perpendicularly to each other.

In some embodiments, the light field detector comprises at least three azimuth detectors, the at least three azimuth detectors configured to cooperate to convert the vector of electromagnetic radiation into a CIE XYZ tristimulus value. In this way, a color output from the combination of the three azimuth detectors enables determination of an absolute position of a light source.

In some embodiments, the light field detector comprises at least three azimuth detectors, wherein the at least three azimuth detectors are oriented such that a first and second azimuth detector are parallel to each other and a third azimuth detector is substantially perpendicular to the first and second azimuth detector.

In some embodiments, the at least two luminescent nanocrystal pixels are parallel to each other.

In some embodiments, the emission wavelengths correspond to colours of red, green, or blue.

In some embodiments, the at least two luminescent nanocrystal pixels is three luminescent nanocrystal pixels. The three luminescent nanocrystal pixels can be stacked together such that they form a semi-cylindrical configuration or a rectangular pyramidal configuration.

In some embodiments, the luminescent nanocrystals pixels comprises perovskite nanocrystals, ZnS:Cu²⁺/Mn²⁺, SrAl₂O₄:Eu²⁺/Dy³⁺ phosphors, upconversion nanoparticles, black phosphorus, or a combination thereof.

In some embodiments, the perovskite nanocrystal is CsPbX₃, wherein X is selected from Cl, Br and/or I.

In some embodiments, the perovskite nanocrystals are characterised by an emission wavelength of about 445 nm, about 523 nm, or about 652 nm.

In some embodiments, each azimuth detector is characterised by a size of about 1×1 μm² to about 200×200 μm².

In some embodiments, the 3D light field detector is characterised by an angular change detection limit of less than 0.015°.

In some embodiments, the light field detector is characterised by an azimuth detector density of about 80 azimuth detectors per mm² to about 200 azimuth detectors per mm².

In some embodiments, the transparent substrate is a polymer substrate, or preferably PDMS.

In some embodiments, the electromagnetic radiation has a wavelength of about 0.002 nm to about 500 nm.

The present invention also provides a 3D light field sensor, comprising:
a) a 3D light field detector as disclosed herein; and
b) a colour charge-coupled device (CCD) electromagnetically coupled to the 3D light field detector for converting the chromatic output into an electric signal.

In some embodiments, the light field sensor further comprises a computer system configured to convert the electric signal into a spatial coordinate in a three-dimensional Cartesian coordinate system.

In some embodiments, the sensor is characterised by an accuracy of about 0.5 mm at a distance of about 0.5 m.

In some embodiments, the sensor is characterised by a spatial sampling density of about 300 points/mm² to about 600 points/mm².

Also disclosed is a method of fabricating a light field detector, comprising:
a) forming or positioning at least one azimuth detector on a transparent substrate, wherein each azimuth detector comprises at least two luminescent nanocrystal pixels having different emission wavelengths relative to each other.

In some embodiments, the step of forming or positioning at least one azimuth detector comprises lithographically patterning the at least two luminescent nanocrystal pixels in a silicon template and curing a polymer over the at least two luminescent nanocrystal pixels in order to form the transparent substrate.

In some embodiments, the step of forming or positioning at least one azimuth detector further comprises lithographically patterning a third luminescent nanocrystal pixel in another silicon template and adhering it to the transparent substrate patterned with the at least two luminescent nanocrystal pixels.

In some embodiments, each of the at least two luminescent nanocrystal pixels comprises nanocrystals dispersed in a polymer matrix.

In some embodiments, the at least two luminescent nanocrystal pixels is each independently characterised by a nanocrystal density of about 0.001 mol/mL to about 0.01 mol/mL.

Forming or positioning at least one azimuth detector on a transparent substrate may comprise arraying azimuth detectors on a transparent substrate such that each azimuth detector is oriented perpendicularly to a neighbouring azimuth detector, wherein each azimuth detector comprises at least two luminescent nanocrystal pixels having different emission wavelengths relative to each other.

In some embodiments, the step of arraying the azimuth detectors comprises lithographically patterning the at least two luminescent nanocrystal pixels in a silicon template and curing a polymer over the at least two luminescent nanocrystal pixels in order to form the transparent substrate.

In some embodiments, the step of arraying the azimuth detectors further comprises lithographically patterning a third luminescent nanocrystal pixel in another silicon template and adhering it to the transparent substrate patterned with the at least two luminescent nanocrystal pixels.

### BRIEF DESCRIPTION OF THE DRAWINGS

Embodiments of the present invention will now be described, by way of non-limiting example, with reference to the drawings in which:

FIG. 1 shows X-ray-to-visible light-field detection using pixelated perovskite nanocrystal arrays. a, Design of the 3D light-field sensor based on pixelated color encoding. Light-field sensing pixels, which consist of patterned perovskite nanocrystals on a transparent film, convert light from different directions into luminescence signals of different colors, detectable by a color CCD. b, The working principle of light-field sensing by color encoding. The basic unit of the 3D light-field sensor is a single azimuth detector comprising multicolor-emitting perovskite nanocrystals. The color of output luminescence depends on the angle a between the incident light and the reference plane. Two perpendicularly arranged azimuth detectors can realize 3D light-field sensing and determine the azimuth angle φ and elevation angle θ of the incident light in spherical coordinates. In an arrangement with three azimuth detectors, correlation of the three azimuth angles a₁, a₂, and a₃ encoded in the color outputs of the three azimuth detectors enables detection of the absolute position (x, y, z) of a light source. c, Chromaticity responses of a single azimuth detector at light incidence from 0 to 360 degrees relative to the reference plane. Red, blue and black dots correspond to the three azimuth angles a₁, a₂, and a₃, recorded using three azimuth detectors shown in (b). d, Chromaticity response of a single perovskite nanocrystal-based azimuth detector at light incidence from 0 to 360°, relative to the control comprising ZnS:Cu²⁺/Mn²⁺ and SrAl₂O₄:Eu²⁺/Dy³⁺ phosphors.

FIG. 2 shows characterizations of pixelated color encoding for 3D light-field sensing. a, Chromaticity responses of single azimuthal detectors composed of three-, four-, and five-color perovskite nanocrystals versus the direction of incident light. b, CIE tristimulus values X, Y, and Z of the output luminescence of a single azimuth detector as a function of the direction of incident light. c, Azimuth resolution measurement for visible light (405 nm) using a single azimuth detector, with a minimum detectable angular change of 0.0018°. d, Two types of color maps recorded from two perpendicularly aligned azimuth detectors with light incident from different azimuth angles @ and elevation angles θ. e, Contour lines extracted from the two color maps in (d). A unique incidence direction can be determined by combining the color values from two azimuth detectors. f, Top view of the azimuthal detector arrays for imaging 3D light field, in which adjacent pixels of perovskite nanocrystals are aligned perpendicularly. The two detectors encircled by the yellow ellipse can determine the angle of the beam incident on the center point of the ellipse. The inset depicts the side view of a patterned pixel. g, Photograph of a 3D light-field sensor fabricated by integrating the perovskite nanocrystal array into a color CCD. The inset shows a section of the microscope image of nanocrystal-based azimuth detectors.

FIG. 3 shows 3D Imaging of real scenes by pixelated color encoding. a, Schematic of the experimental setup. Multiline structured light is incident on the object, lens 1 and lens 2 capture the reflected light and pass it to perovskite nanocrystal arrays. A color CCD then measures the color of each azimuth detector to calculate the corresponding distance to the scenes. b, Representative images of perovskite nanocrystal arrays with incident light from different directions. c, Depth precision given by the standard deviation of repeated depth measurements and plotted as a function of scene depth and radial position in the field of view. A movable, flat, white screen is used as the target object. D-f, 3D images of scenes placed at 0.7 m, 1.5 m, and 3 m, respectively.

FIG. 4 shows wavefront imaging of X-rays (0.089 nm) and visible light (405 nm) by pixelated color encoding. a, Principles of the Hartmann or Shack-Hartmann wavefront imaging method (top) and wavefront imaging method based on our 3D light-field sensor arrays (bottom). (b and c) Measurement of a diverging wavefront of X-rays 14 mm and 20 mm from the X-ray source, respectively. (d and e) Wavefronts measured in the image plane when a lens is illuminated by visible light at (Fₓ=0°, F_{y}=20° and (Fₓ=30°, F_{y}=40° field angles, respectively. Fₓ and F_{y} represent the field angles of the illumination beam in the X and Y directions, respectively. The focal length and aperture of the lens are 60 mm and 25.4 mm, respectively.

FIG. 5 shows a schematic of the fabrication process of the pixelated perovskite nanocrystal arrays.

FIG. 6 shows example of raw color images taken at different incident angles. When θ increases from −40° to 40° with φ=0°, the blueness of the pixel in the yellow square gradually fades. When θ increases from −40° to 40° with φ=90°, the blueness of the pixel in the red square becomes gradually weaker.

FIG. 7 shows experimental setup of 3D imaging. A multiline structured light source (405 nm, Shenzhen Infrared Laser Technology Co., Ltd.) was generated by collimating and extending a light through a combination of a collimator and beam expander to an optical grating. An objective lens, consisting of lens 1 with a focal length of 100 mm and lens 2 with a focal length of 25 mm, collects the light reflected by the object and transmits it to the 3D light-field sensor comprising perovskite nanocrystal arrays.

FIG. 8 shows experimental setup and results of spherical wavefront measurement with perovskite nanocrystal arrays. a, Experimental setup for wavefront measurement based on perovskite nanocrystal imaging arrays. b-e, Measured wavefront at z=5 mm, 6 mm, 7 mm, and 8 mm, respectively.

FIG. 9 shows geometric model of the 3D imaging system based on the triangulation method.

FIG. 10 shows 2D geometric schematic of the designed imaging system.

FIG. 11 shows a schematic of the calibration of a multiline structured light source.

### DETAILED DESCRIPTION

Light-field detection is a technology that captures both the intensity and the precise direction of light rays in free space. However, current light-field detection techniques either require complex microlens arrays or are limited to the ultraviolet-visible wavelength ranges. The present invention provides a scalable method based on lithographically patterned perovskite nanocrystal arrays that can determine the radiation vector of incident rays in the wavelength range from X-rays to visible light (0.002-700 nm). Multicolor-emitting perovskite nanocrystals can convert light rays from a specific direction into a pixelated color output with an angular resolution of 0.0018°, which is two orders of magnitude higher than conventional angle-sensing photodetectors. 3D light-field detection and spatial positioning of light sources are possible by modifying nanocrystal arrays with specific orientations. The validity of 3D object imaging and visible light/X-ray wavefront imaging is validated by combining pixelated perovskite nanocrystal arrays with a color charge-coupled device. The ability to image light fields beyond optical wavelengths through color-contrast encoding could open up new applications from 3D phase-contrast imaging to robotics, virtual reality, tomographic biological imaging, and satellite autonomous navigation.

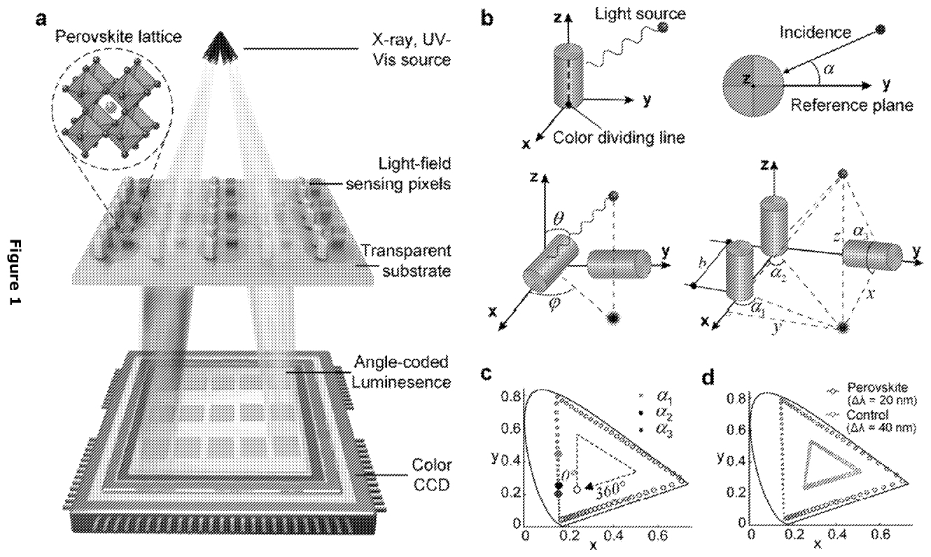

Inspired by the versatility of color encoding in data visualization, the inventors hypothesized that color contrast encoding could be used to visualize directions of light rays. To test the hypothesis, inorganic perovskite nanocrystals were selected as candidates because they have excellent optoelectronic properties. They also exhibit highly efficient and tunable emission with high color saturation across the visible spectrum under X-ray or visible light irradiation. A fundamental design for 3D light-field detection involves lithographical patterning of perovskite nanocrystals on a transparent substrate (FIG. 1a). A 3D light-field sensor can then be constructed by integrating the patterned thin-film substrate with a color charge-coupled device (CCD) that converts the angle of incident light rays into a specific color output.

The basic unit of the light field detector or 3D light-field sensor is a single azimuth detector comprising multicolor-emitting perovskite nanocrystals. Since the absorption of light or radiation of the patterned nanocrystals changes with the incident direction of light, there is a mapping between the color of luminescence and the azimuth angle of excitation light. When incident light strikes patterned nanocrystals, the azimuth angle a between the incident light and the reference plane can be detected by measuring the color output of the basic unit (FIG. 1b). Specifically, two azimuth detectors arranged perpendicular to each other can realize 3D light direction sensing and determine the azimuth angle φ and elevation angle θ of the incident light in spherical coordinates. To determine the absolute position of a light source, three azimuth detectors can be arranged to create a correlation among the three corresponding azimuth angles a₁, a₂, and a₃ encoded in the color outputs.

In the three-dimensional Cartesian coordinate system, two detectors (A and B) are perpendicular to the XOY plane at coordinates (b, 0, 0) and coordinates (0, 0, 0), and a third detector (C) is arranged parallel to the XOY plane along the Y axis. Assuming that the X axis is the reference direction, the projection of the light or radiation source S onto the XOY plane is S′, the angle between the line (connecting S′ and detector A) and the reference direction is a₁, and the angle between the line (connecting S′ and detector B) and the reference direction is a₂. The angle between the line (connecting S and the detector C) and the XOY plane is a₃. a₁, a₂, and a₃ are determined by the color of the luminescence of azimuth detectors A, B and C, respectively. Therefore, the spatial position (x, y, z) of the source S can be solved by the following formula:

$$x = \frac{b tan {α}_{1}}{tan {α}_{1} - tan {α}_{2}} , y = \frac{b tan {α}_{1} tan {α}_{2}}{tan {α}_{1} - tan {α}_{2}} , z = \frac{b tan {α}_{1} tan {α}_{3}}{tan {α}_{1} - tan {α}_{2}}$$

Accordingly, the present invention provides a 3D light field detector for converting a vector of an electromagnetic radiation into a chromatic output, comprising at least one azimuth detector on a transparent substrate, the at least one azimuth detector comprising at least two luminescent nanocrystal pixels having different emission wavelengths relative to each other.

The light field detector may comprise at least two said azimuth detectors oriented perpendicularly to each other.

In some embodiments, the light field detector comprises at least three azimuth detectors, the at least three azimuth detectors configured to cooperate with each other to convert the vector of electromagnetic radiation into a CIE XYZ tristimulus value. The CIE color model is a mapping system that uses tristimulus (a combination of 3 color values that are close to red/green/blue) values, which are plotted on a 3D space. When these values are combined, they can reproduce any color that a human eye can perceive. In this way, a color output from the combination of the three azimuth detectors enables determination of an absolute position of a light source.

In some embodiments, the at least three azimuth detectors are oriented such that a first and second azimuth detector are parallel to each other and a third azimuth detector is substantially perpendicular to the first and second azimuth detector.

In some embodiments, the light field detector comprises an array of azimuth detectors on a transparent substrate, each azimuth detector oriented perpendicularly to a neighbouring azimuth detector;
wherein each azimuth detector comprises at least two luminescent nanocrystal pixels having different emission wavelengths relative to each other.

In some embodiments, the light field detector comprises an array of azimuth detectors on a transparent substrate, wherein each azimuth detector is in a same orientation relative to an alternate azimuth detector.

In some embodiments, the at least two luminescent nanocrystal pixels are parallel to each other. In other embodiments, at least two luminescent nanocrystal pixels are arranged at an angle relative to each other. The angle may be less than 90°, or less than 45°.

Each luminescent nanocrystal pixel is configured to emit a wavelength of a particular colour. The at least two luminescent nanocrystal pixels are configured to emit wavelengths which are different from each other. In some embodiments, the emission wavelengths each correspond to colours of red, green, or blue. In some embodiments, the emission wavelengths correspond to at least two colours selected from red, green, or blue. Other colours can also be used.

In some embodiments, the at least two luminescent nanocrystal pixels is three luminescent nanocrystal pixels. The three luminescent nanocrystal pixels can be stacked together such that they form a semi-cylindrical configuration or a rectangular pyramidal configuration. In this regard, each luminescent nanocrystal pixel is configured such that it has a rectangular morphology or forms a sector of a cylinder.

Each luminescent nanocrystal pixel comprises a plurality of nanocrystals. Each luminescent nanocrystal pixel comprises a particular type of nanocrystals or combination thereof in order to have an emission wavelength of a specific colour. By combining luminescent nanocrystal pixels each of separate and different or different ratios of nanocrystals, the luminescent nanocrystal pixels may each emit light of a different wavelength when excited. In some embodiments, the luminescent nanocrystals pixels comprises perovskite nanocrystals, ZnS:Cu²⁺/Mn²⁺, SrAl₂O₄:Eu²⁺/Dy³⁺ phosphors, upconversion nanoparticles, black phosphorus, or a combination thereof. In some embodiments, the luminescent nanocrystals pixels comprises perovskite nanocrystals. In some embodiments, the luminescent nanocrystals pixels comprises isotropic nanocrystals.

In some embodiments, the perovskite nanocrystal is CsPbX₃, wherein X is selected from Cl, Br and/or I. For example, the perovskite nanocrystals may be CsPbBr₃ and/or CsPbCl₃.

In some embodiments, the nanocrystals are characterised by a particle size of about 10 nm to about 50 nm. In other embodiments, the particle size is about 10 nm to about 40 nm, about 10 nm to about 30 nm or about 10 nm to about 20 nm. In other embodiments, the particle size is about 20 nm.

In some embodiments, the perovskite nanocrystals (and hence the luminescent nanocrystals pixels) are characterised by an emission wavelength of about 445 nm, about 523 nm, or about 652 nm. Depending on the colour selected, the wavelength can be altered.

In some embodiments, each azimuth detector is characterised by a size of about 1×1 μm² to about 200×200 μm², or about 1×1 μm² to about 100×100 μm². The size of the azimuth detector is an accumulation of the luminescent nanocrystal pixels.

In some embodiments, the azimuth detectors are spaced apart from each other by about 5 μm to about 20 μm. In other embodiments, the spacing is about 5 μm to about 18 μm, about 5 μm to about 16 μm, about 5 μm to about 14 μm, about 5 μm to about 12 μm, about 5 μm to about 10 μm, about 5 μm to about 8 μm, or about 5 μm to about 7 μm.

In some embodiments, the azimuth detectors are characterised by an azimuth detector density of about 80 azimuth detectors per mm² to about 200 azimuth detectors per mm². In other embodiments, the azimuth detector density is about 100 azimuth detectors per mm²,

In some embodiments, the 3D light field detector is characterised by an angular change detection limit of less than 0.015°, or less than 0.003°, or preferably about 0.0018°. The angular change detection limit is the vector sensitivity.

In some embodiments, the transparent substrate is a polymer substrate, or preferably PDMS.

In some embodiments, the electromagnetic radiation has a wavelength of about 0.002 nm to about 700 nm, or about 0.002 nm to about 500 nm.

The present invention also provides a 3D light field sensor, comprising:
a) a 3D light field detector as disclosed herein; and
b) a colour charge-coupled device (CCD) electromagnetically coupled to the 3D light field detector for converting the chromatic output into an electric signal.

In some embodiments, the 3D light field detector is coated on the colour CCD.

The colour CCD may be SONY ICX274AL sensor with a chip size of 10 mm×14 mm (horizontal by vertical), providing 24-bit RGB true colors. Alternatively, a 30-bit color display with 10-bit color depth may be used.

The CCD may have a photosensitive area of about 10 mm by about 20 mm, or about 10 mm by about 14 mm. The CCD may have a pixel size of about 1 by 1 μm² to about 5 by 5 μm², or about 2.5×2.5 μm².

In some embodiments, the 3D light field sensor further comprises a lenses for light collection.

In some embodiments, the 3D light field sensor further comprises a computer system or controller configured to convert the electric signal into a spatial coordinate in a three-dimensional Cartesian coordinate system. As will be understood, the controller will generally be embodied by electronic components, particularly electronic components programmed to convert the electric signal into a spatial coordinate based on the formula as mentioned herein.

In some embodiments, the sensor is characterised by an accuracy of about 0.5 mm at a distance of about 0.5 m.

In some embodiments, the sensor is characterised by a spatial sampling density of about 300 points/mm² to about 600 points/mm², or about 400 points/mm².

The present invention also provides a wavefront sensor, comprising the 3D light field sensor as disclosed herein. The 3D light field sensor may be about 5 mm to about 100 mm away from a light source.

The present invention also provides a method of fabricating a 3D light field detector, comprising:
a) forming or positioning at least one azimuth detector on a transparent substrate;
wherein the at least one azimuth detector comprises at least two luminescent nanocrystal pixels having different emission wavelengths relative to each other.

In some embodiments, the step of forming or positioning at least one azimuth detector comprises lithographically patterning the at least two luminescent nanocrystal pixels in a silicon template and curing a polymer over the at least two luminescent nanocrystal pixels in order to form the transparent substrate.

In some embodiments, each of the at least two luminescent nanocrystal pixels comprises a plurality of nanocrystals dispersed in a polymer matrix. In some embodiments, the plurality of nanocrystals is homogenously dispersed in the polymer matrix. In some embodiments, the at least two luminescent nanocrystal pixels is each independently characterised by a nanocrystal density of about 0.001 mol/mL to about 0.01 mol/mL. In other embodiments, the nanocrystal density of about 0.002 mol/mL to about 0.01 mol/mL, about 0.003 mol/mL to about 0.01 mol/mL, about 0.004 mol/mL to about 0.01 mol/mL, about 0.004 mol/mL to about 0.009 mol/mL, about 0.004 mol/mL to about 0.008 mol/mL, about 0.004 mol/mL to about 0.007 mol/mL, or about 0.004 mol/mL to about 0.006 mol/mL.

In some embodiments, the plurality of nanocrystals is dispersed in a transparent polymer matrix. The polymer may be a silicon based polymer.

In other embodiments, the method comprises:
a) forming or positioning at least three azimuth detectors on a transparent substrate such that the at least three azimuth detectors are configured to cooperate to convert the vector of electromagnetic radiation into a CIE XYZ tristimulus value;
wherein the at least one azimuth detector comprises at least two luminescent nanocrystal pixels having different emission wavelengths relative to each other.

In other embodiments, the method comprises:
a) arraying azimuth detectors on a transparent substrate such that each azimuth detector is oriented perpendicularly to a neighbouring azimuth detector;
wherein each azimuth detector comprises at least two luminescent nanocrystal pixels having different emission wavelengths relative to each other.

In some embodiments, the step of arraying the azimuth detectors comprises lithographically patterning the at least two luminescent nanocrystal pixels in a silicon template and curing a polymer over the at least two luminescent nanocrystal pixels in order to form the transparent substrate.

In some embodiments, the step of arraying the azimuth detectors further comprises lithographically patterning a third luminescent nanocrystal pixel in another silicon template and adhering it to the transparent substrate patterned with the at least two luminescent nanocrystal pixels.

The present invention also provides a method of fabricating a 3D light field sensor, comprising electromagnetically coupling a colour charge-coupled device (CCD) to the 3D light field detector for converting the chromatic output into an electric signal.

Each azimuth detector comprising multicolor-emitting materials which converts EM rays incident from a specific direction into a unique color output. In this way, light fields can be measured without complex microlens arrays and photonic crystal processing. This is applicable to a variety of color-tunable luminescent materials, and has no wavelength and polarization dependence.

When two azimuth detectors arranged perpendicular to each other, they can realize 3D light-field sensing. In the arrangement with three azimuth detectors, correlation of the three azimuth angles a₁, a₂, and a₃ encoded in the color outputs of the three azimuth detectors enables absolute position determination of a light source. Compared with conventional angle detectors, the azimuth detector arrays can be easily modified with specific orientations to achieve more advanced applications, such as source localization, which cannot be achieved by conventional angle detectors.

In some embodiments, an array for 3D light-field imaging detector was designed and fabricated, in which adjacent azimuthal detectors are aligned perpendicular to each other. 3D light field imaging arrays can be used for 3D imaging of objects and wavefronts. The two azimuthal detectors are perpendicular to each other, allowing each detector pixel to be multiplexed, thereby increasing the imaging resolution. Importantly, the detector arrays are fabricated on a transparent substrate film through a simple demolding process, which can be directly integrated into a color CCD to construct a light-field image senor without complicated fabrication processes.

In particular, a single azimuth detector composed of perovskite nanocrystal can enable light-field detection in the wavelength range of 0.002-500 nm with 0.0018° angular resolution. Further, a thin film fabricated with patterned perovskite nanocrystal arrays is integrated on a color CCD for 3D imaging of objects and wavefronts. With the current structure design, a vector sensitivity of 0.015° and a wavelength response range of 0.002-500 nm can be achieved, which is about 100 times and 200 times better than conventional microlens-based detection methods, respectively.

A detailed description of the workings of the invention is laid out below. In the embodiments that follows, the invention is described in relation to some conditions for consistency to showcase the present invention. However, the skilled person would understand that the invention is not limited to such.

As an example, inorganic perovskite nanocrystals (CsPbX₃; X=Cl, Br, I) was synthesised. Three sets of perovskite quantum dots were selected with emissions at 445 nm, 523 nm, and 652 nm to construct a single azimuth detector. When light is incident from 0 to 360 degrees relative to the reference direction, the detected color gamut forms a large triangle on the CIE xy chromaticity diagram (FIG. 1c). The position of the color output on the chromaticity diagram determines the incident angle of the light, and a larger triangle indicates higher angular resolution. We found that the color gamut of azimuth detectors made of perovskite nanocrystals forms a larger triangle in the chromaticity diagram compared to detectors made of ZnS:Cu²⁺/Mn²⁺ and SrAl₂O₄:Eu²⁺/Dy³⁺ phosphors (FIG. 1d). This constructs higher angular resolution, which is due to the broader color coverage and higher color saturation of perovskite nanocrystals.

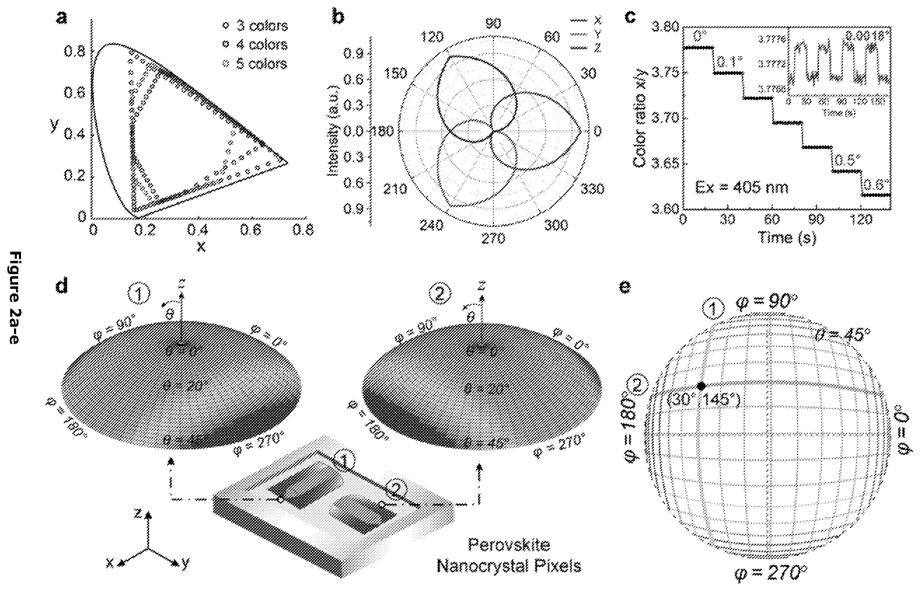

Single azimuth detectors with different color gamuts produce color plots of varying shape (FIG. 2a). Intriguingly, nanocrystals with red, green, and blue color output can detect extremely small angular changes. This property was exploited and a single three-color azimuth detector on an RGB sensor chip was built that converts incident light from 0 to 360 degrees into different CIE XYZ tristimulus values of luminescence (FIG. 2b). The minimum detectable angular change is determined by the contrast ratio of the color response and by the signal-to-noise ratio (SNR) of the color sensor. In our measurements, each primary color has 65536 levels, resulting in a detection limit of 0.0018° angular change at a wavelength of 405 nm and a power of 8 mW (FIG. 2c).

We next designed and fabricated two azimuth detectors arranged perpendicular to each other for omnidirectional light-field detection (FIG. 2d). In spherical coordinates, the azimuth angle φ and elevation angle θ for each incident beam can be calculated using the formula: φ=arctan(tan a₁/tan a₂) and θ=arctan(\sqrt{tan² a₁+tan² a₂}), respectively, where a₁ and a₂ are obtained from the emission colors of the two azimuth detectors. Two azimuth detectors yielded two types of color maps at different angles of incidence. The contours of the two color maps in the polar plot allow for specific incidence angles to be determined by combining the color values of two azimuth detectors (FIG. 2e). We further designed azimuthal detector arrays to image 3D light field, in which adjacent pixels of perovskite nanocrystals were aligned perpendicular to each other (FIG. 2f). For simplicity, the angle detected by detectors parallel to the x-axis is denoted by a_{i,j} (i and j refer to the rows and columns of the nanocrystal arrays), and the angle detected by detectors parallel to the y-axis is denoted by a_{i,j}. Each of the two azimuth detectors, which are perpendicular to each other, can reconstruct the angle of the beam incident at the center of the two pixels. For example, a_{1,1} and β_{1,2} can be used to calculate the 3D angle of the beam incident at point s₁₁, whereas β_{2,1} and a_{1,1} can be used to calculate the 3D angle of the beam incident at point s₂₁. Therefore, the imaging spatial resolution of the nanocrystal arrays is determined by the distance between s₁₁ and s₁₂. We next integrated a thin film of perovskite nanocrystal arrays into a digital camera equipped with a color CCD (FIG. 2g). The CCD has a photosensitive area of 10 mm×14 mm and a pixel size of 2.5×2.5 μm². The pixel size of a single azimuth detector is 50×50 μm² and covers a total of 400 CCD pixels.

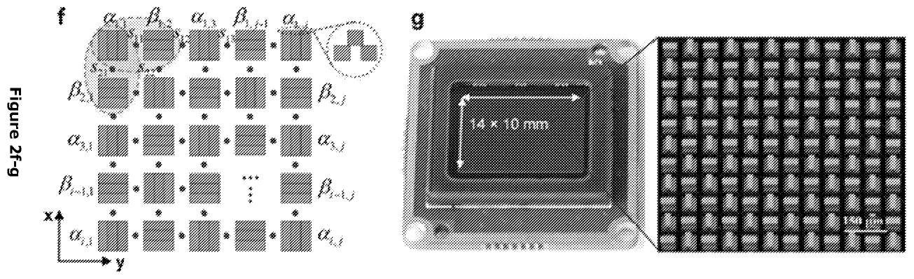

A direct application of the light-field sensor based on pixelated perovskite nanocrystal arrays is 3D imaging and Light Detection and Ranging (LIDAR) (FIG. 3a). This imaging system is based on a triangulation method and consists of a multiline structured light source, two lenses for light collection, and a color CCD coated with a thin film of nanocrystal arrays. The object distance z is determined by measuring the angle of the light reflected to the nanocrystal arrays by the object, meaning that a high angular resolution provides a high depth resolution. For a given pixel size (50×50 μm²), the theoretical depth resolution and detectable range are improved by ˜10 times and ˜3 times, respectively, compared with conventional triangulation methods. To improve data accuracy, these nanocrystal arrays were calibrated first and then the imaging system was calibrated (FIG. 3b). Under light incidence from different angles θ and ϕ, images captured by perovskite nanocrystal array serve as a corresponding map of the color response of each azimuth detector and the angle of incident light. To quantitatively evaluate the imaging performance of the prototype, we measured its depth accuracy as a function of scene depth and radial position within the field of view (FIG. 3c). These measurements revealed an optimal depth accuracy of ˜0.5 mm at 0.5 m distance, though the depth accuracy slightly decreased to ˜1.5 mm at 2 m distance. Detector depth accuracy may be affected by the power and angle of incident light. To ensure high angular resolution, the light source power of the structured light source is adjusted to be sufficient. The depth accuracy also varies depending on the intensity of the background light when the detector is used in natural light or light bulb conditions. The dimensions of objects imaged by the light-field sensor at different distances (0.7, 1.5 and 3 m) with the light-field sensor agree with the actual dimensions of the objects (FIG. 3d-f). Image reconstruction is also possible for objects with fine structures, such as keyboards and combs (FIG. 3f). Insufficient light returned or random noise may result in undetected pixels. Moreover, we obtained 3D images of several objects of varying colors, sizes, and materials at increasing depths using the pixelated color conversion strategy.

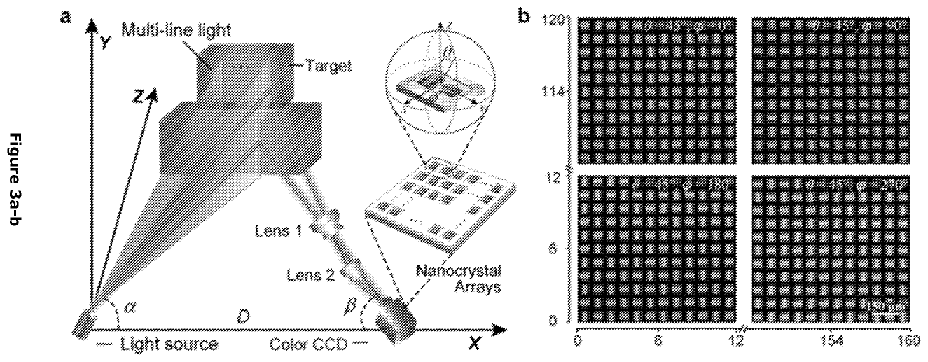

Another important application of pixelated color conversion is phase contrast imaging in the ultra-broad wavelength range from X-rays to visible light (0.002-500 nm). In phase contrast imaging with a conventional Shack-Hartmann wavefront sensor, arrays of microlenses record the angle of incidence onto a series of grid points that determine the wavefront (FIG. 4a). A nanocrystal array-based light-field sensor can directly measure the specific angle of visible light or X-rays to reconstruct the wavefront without microlens arrays. We first characterized the diverging wavefront of a hard X-ray beam by placing the light-field sensor at 14 mm and 20 mm from the X-ray source (FIGS. 4b and 4c). The curvature of the measured wavefront agrees well with analytical calculations, and the maximum angle measured by the light-field sensor is 40.6°. We also demonstrated the mapping of visible light wavefronts in the image plane when a lens was illuminated by the visible light at two different field angles (FIGS. 4d and 4e). Furthermore, phase contrast imaging was performed using visible light on polydimethylsiloxane (PDMS) patterns and X-rays on commercial polymethymethacrylate (PMMA) rods (FIGS. 4f and 4g). Surface structures can be seen with greater detail by phase contrast imaging than absorption contrast imaging.

The fabrication of nanocrystal light-field sensors is highly robust with high uniformity over a large area compared with microlens array fabrication. In our experiment, the spatial sampling density is 400 points/mm², angular resolution is 0.015°, and the dynamic angular range is greater than 90 degrees. In contrast, commercial Shack-Hartmann sensors (Thorlabs WFS30-5C) typically have a low sampling density of 44 points/mm² and a small dynamic angular range of <2°. The nanocrystal light-field sensor is also applicable to a wider spectral range.

In conclusion, we have presented a pixelated color conversion strategy based on perovskite nanocrystal arrays for 3D light field detection, absolute spatial positioning, 3D imaging, and visible light/X-ray phase contrast imaging. With its current design, we have achieved a vector sensitivity of 0.0018° and a wavelength response range of 0.002-700 nm, which are nearly 100 times and 200 times better than conventional microlens-based detection methods, respectively. Further improvement in angular precision is possible by integrating high-end color detectors. For example, a 30-bit color display with 10-bit color depth can yield 1.07 billion possible combinations. With advanced lithography methods and state-of-the-art processing, azimuth detector densities in excess of 104 pixels/mm² should be achievable, which could greatly improve spatial resolution in imaging. Moreover, the pixelated color encoding strategy for light-field detection and imaging can be readily extended to optical materials beyond the perovskite nanocrystals presented here. Sn-based perovskite nanocrystals, near-infrared-responsive upconversion nanoparticles or black phosphorus with tunable bandgaps can expand angular detection to the near-infrared and even the micrometer wavelength range. In addition, compared to Shack-Hartmann sensors, light-field sensors based on nanocrystal arrays can be directly integrated into the on-chip optical systems to measure wavefronts or phase. Since azimuth detectors can only distinguish the average vector direction of incident light, not the light from multiple directions like a light-field camera, our light-field sensors measure the average vector direction of light at each pixel. As with light-field cameras, nanocrystal light-field sensors must balance between angular and spatial resolution. Scanning light-field imaging systems can be coupled with nanocrystal arrays to further improve spatial resolution. Nonetheless, the ability to map the wavefront of high-energy X-rays provides powerful solutions for optics testing and beam characterization, while opening new applications ranging from phase-contrast imaging to gravitational wave detection.

### Methods

### Chemicals

Cesium carbonate (Cs₂CO₃, 99.9%), lead (II) chloride (PbCl₂, 99.99%), lead (II) bromide (PbBr₂, 99.99%), lead (II) iodide (PbI₂, 99.99%), oleylamine (technical grade 70%), oleic acid (technical grade 90%), 1-octadecene (technical grade 90%) and cyclohexane (chromatography grade 99.9%) were purchased from Sigma-Aldrich. A Sylgard 184 silicone elastomer kit was purchased from Dow Corning for the preparation of polydimethylsiloxane (PDMS) substrates. ZnS/CdSe phosphorus powders were purchased from Xiucai Chemical Co., Ltd. (Foshan, China).

### Synthesis and Characterization

CsPbX₃ (X=Cl, Br, or I) perovskite nanocrystals were synthesized according to a method described in the literature. First, cesium oleate was synthesized as a cesium precursor, and then CsPbX₃ perovskite nanocrystals were synthesized using the modified hot-injection method.

Transmission electron microscopy (TEM) of the synthesized perovskite nanocrystals was performed using a FEI Tecnai G20 transmission electron microscope with an accelerating voltage of 200 kV. Under visible light or X-ray excitation, perovskite quantum dots (QDs) give off narrow and color-tunable visible emission. Photoluminescence and radioluminescence spectra were obtained using an Edinburgh FS5 fluorescence spectrophotometer (Edinburgh Instruments Ltd, UK) equipped with a miniature X-ray source (AMPEK, Inc.). An advantageous property of perovskites as detectors is their linear response to X-ray dose rate or excitation light power with coverage up to several orders of magnitude. The lowest detectable dose rate for X-ray detection was demonstrated to be 10.8-13 nGy s⁻¹, and the lowest detectable power for optical detection was 1 pW/mm⁻². Perovskite QDs also exhibit a very fast response (decay time, τ=10.4 ns) to pulsed excitation. These nanocrystals show high photostability under successive or repeated cycles of X-ray irradiation and photoexcitation.

### Fabrication and Integration of 3D Light-Field Sensor Arrays

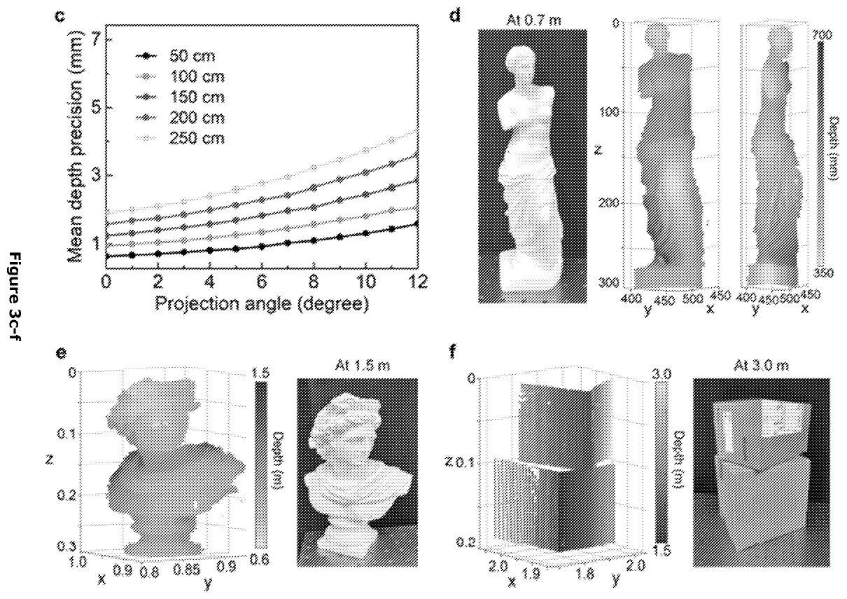

The 3D light-field sensor based on pixelated perovskite nanocrystal arrays were fabricated by a simple moulding process (FIG. 5). First, the pre-patterned Si template was sufficiently washed with heptane. Colloidal QD solutions were prepared by redispersing the as-synthesized red, green, and blue QDs in a cyclohexane solution with vigorous stirring. A 10:1:1 (v:v:v) mixture of SYLGARD silicone elastomer 184, curing agent and QDs in cyclohexane (5 mol %) was prepared. Then, the prepared red-emitting QD-PDMS ink and blue-emitting QD-PDMS ink were injected into the corresponding rectangular holes on the Si template and cured at 90° C. for 30 min. The top of the injected QDs ink must be flush to the top of the Si template. Next, 0.5 mm thick PDMS was spun onto the surface of the Si template as an adhesive film. After curing at 90° C. for 30 min, the PDMS film patterned with red and blue pixels was moulded off the Si template. Similarly, green-emitting quantum dot ink was injected into another Si template and cured at 90° C. for 30 min hour. Then, a layer of transparent PDMS was coated on the previously processed PDMS film printed with red and blue pixels, which was then overlaid on the green-emitting ink injected template on the holder of the mask aligner. Finally, after curing at 90° C. for 30 min, a film with red, green and blue pixel arrays was obtained by a mould release process. 3D light-field sensor was formed by integrating the processed pixelated perovskite nanocrystal array film to a color CCD, with each angle-sensitive pixel covering multiple CCD pixels. The color CCD is a SONY ICX274AL sensor with a chip size of 10 mm×14 mm (horizontal by vertical), providing 24-bit RGB true colors.

In current 3D printed molds, the size can be adjusted from tens of micrometers to several millimeters. Large-scale manufacturing is possible through repeated demolding. This method eliminates the need for complex semiconductor processes and special gases, which greatly reduces processing costs. Fabrication errors typically include random defects and alignment errors. Since the demolding process used in this work has high machining accuracy and edge defects can be controlled within 0.1%, the random defect error of the entire azimuth detector pixel is almost negligible. A layer alignment error occurs during processing, due to the need to align upper and lower layers. In cases where the image distance is much greater than a single color pixel's thickness, alignment deviation will not affect angle measurement.

### Calibration of the 3D Light-Field Sensor

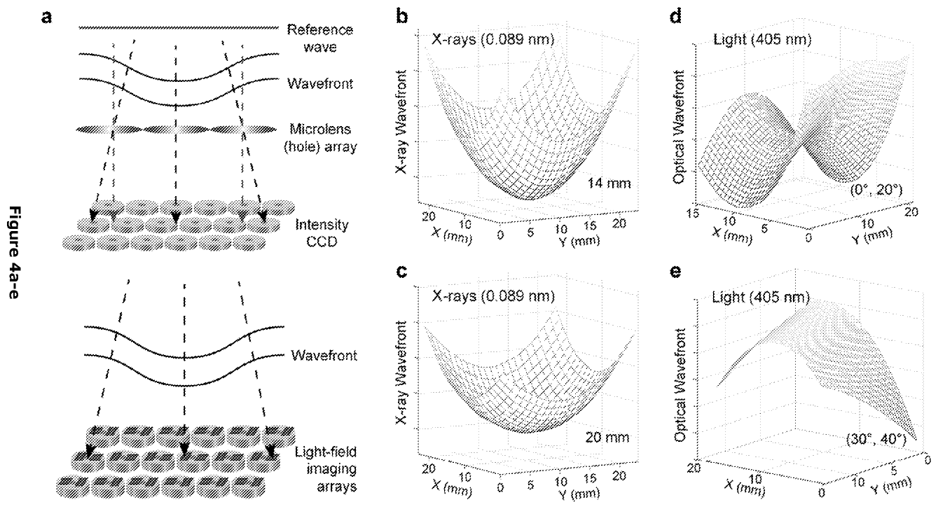

The 3D light-field sensor based on perovskite nanocrystal arrays was calibrated under a collimated LED light source. A motorized rotation stage (Daheng Optics, GCD-011060M), a pitch platform, and a linear stage were connected to rotate the 3D light-field sensor in θ and ϕ directions. The image sensor was attached to the pitch platform. The pitch platform moves in the θ direction, and the rotatory stage moves in the ϕ direction. A linear stage is used to compensate the off-axis movement of the image sensor when it rotates in θ direction. We present selected raw color images captured during the calibration process to illustrate the working principle of 3D light-field sensor (FIG. 6). Each panel depicts a cropped region of the raw color image taken at different incident angles. Here, we can observe the angular dependence of the color output of each pixel. The yellow square represents a vertical angle sensitive unit and the red square represents a horizontal angle-sensitive unit. When θ increases from −40° to 40° with φ=0°, the blueness of the pixel in the yellow square gradually becomes weaker. When θ increases from −40° to 40° with φ=90°, the blueness of the pixel in the red square becomes gradually weaker. Once the calibration is completed for the entire range of θ and ϕ, the captured raw images are used as a lookup table for individual angle detection pixels that determine the incident angle of light.

### 3D Imaging Procedure

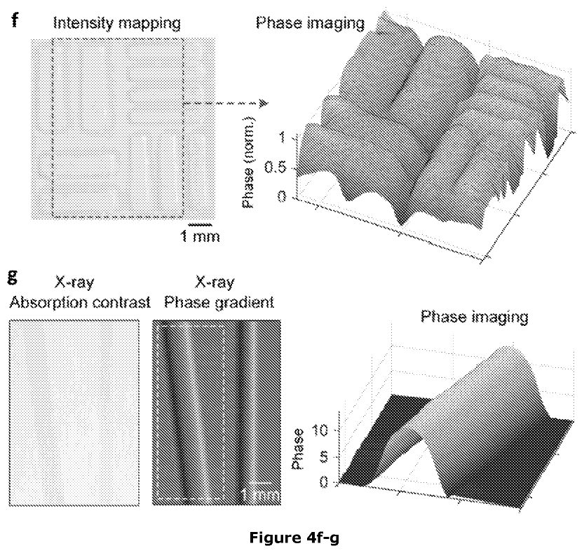

The home-built optical setup for 3D imaging consists of a light source and an optical grating to generate multiline structured light on the 3D scene to be imaged (FIG. 7). The reflected/scattered light from the object is collected by a homemade objective consists of two lenses optimized for focal lengths of 100 mm and 25 mm, respectively, allowing maximum angular variation for different object distances identified by the developed high-resolution 3D light-field sensor. In a typical experiment, the parameters of the multiline structured light and the camera, as well as the relative distance between them were first calibrated. Next, the color output of each detector was mapped to the angular arrays according to calibrated results, and then we can calculate the spatial coordinates x, y, and z of the object point corresponding to each angular detection unit according to the geometric model of the 3D imaging system as discussed below.

### Spherical X-Ray Wavefront Measurement

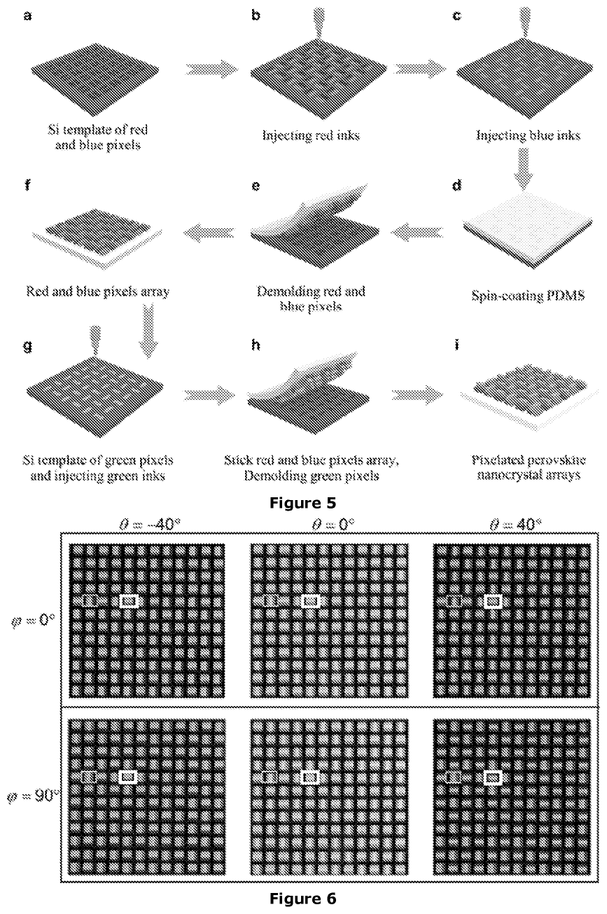

A 3D light-field sensor was used to measure the wavefront of spherical hard X-rays (14 keV) (FIG. 8). The X-ray source produces a divergent beam with a divergence angle of approximately 90 degrees whose wavefronts are measured at different positions. The further the 3D light-field sensor moves away from the X-ray source, the smaller the measured radius of curvature of the spherical wavefront becomes. Furthermore, from the reconstructed wavefront and slope mapping we can identify the tilt angle between the X-ray source and the sensor. As a proof of principle, color data mapping at z=5 mm was used as calibration data for reconstructing wavefronts at other distances z, resulting in less accurate slope measurements with increasing z. In practical applications, sampling angles must be obtained in sufficient numbers to ensure angular resolution.

### Phase Contrast Imaging Procedure

In phase contrast imaging utilizing collimated UV/visible light, the object is a patterned PDMS substrate with a strip thickness of 0.6 mm. The light-field imaging sensor is placed directly behind the object to capture an image of the changed wavefront. To obtain a nearly collimated beam for X-ray phase contrast imaging, a copper-column collimator is positioned behind the radiation source. Two commercial PMMA rods of 1 mm and 2 mm in diameter are placed behind the radiation source, and the light-field imaging sensor detects the changed wavefront. Specifically, the light-field imaging sensor acquires pixelated beam angles, which characterize the phase gradient distribution. After performing median filtering and integration on the phase gradient, phase mapping can be achieved.

### The Positioning Principle and Error Analysis

The photoluminescence part of the azimuth detector consists of three sets of CsPbX₃ nanocrystals, which emit red, green, and blue light. Since the absorption of light or radiation of each part changes with the incident direction of light, there is a mapping between the color of luminescence and the azimuth angle of excitation light. Each azimuth detector can determine the angle a of the incident beam with respect to the reference plane, so three such azimuth detectors can be arranged to locate the spatial position of the excitation source. In the three-dimensional Cartesian coordinate system, detector A and detector B are perpendicular to the XOY plane at coordinates (b, 0, 0) and coordinates (0, 0, 0), and cylinder C is arranged parallel to the XOY plane along the Y axis. Assuming that the X axis is the reference direction, the projection of the light or radiation source S onto the XOY plane is S′, the angle between the line (connecting S′ and detector A) and the reference direction is θ1, and the angle between the line (connecting S′ and detector B) and the reference direction is θ2. The angle between the line (connecting S and the detector C) and the XOY plane is θ3. θ1, θ2, and θ3 are determined by the color of the luminescence of azimuth detectors A, B and C, respectively. Therefore, the spatial position (x, y, z) of the source S can be solved by the following formula:

$$\{ \begin{matrix}tan {θ}_{1} = \frac{y}{x - b} \\ tan {θ}_{2} = \frac{y}{x} \\ tan {θ}_{3} = \frac{z}{x}\end{matrix} ⟹ \{ \begin{matrix}x = \frac{b tan {θ}_{1}}{tan {θ}_{1} - tan {θ}_{2}} \\ y = \frac{b tan {θ}_{1} tan {θ}_{2}}{tan {θ}_{1} - tan {θ}_{2}} \\ z = \frac{b tan {θ}_{1} tan {θ}_{3}}{tan {θ}_{1} - tan {θ}_{2}}\end{matrix}$$

The positioning errors dx, dy and dz of the source S depend on the angular detection error dθ of each azimuth detector, the distance b, and the position coordinates x, y, and z of the source. The dx, dy and dz as a function of dθ are:

$$dx = b \frac{{( tan {θ}_{1} )}^{′} d θ}{tan {θ}_{1} - tan {θ}_{2}} + b tan {θ}_{1} [ \frac{{( tan {θ}_{1} )}^{′} d θ - {( tan {θ}_{2} )}^{′} d θ}{- {( tan {θ}_{1} - tan {θ}_{2} )}^{2}} ] = b [ \frac{tan {{θ}_{1} ( tan {θ}_{2} )}^{′} - tan {{θ}_{2} ( tan {θ}_{1} )}^{′}}{{( tan {θ}_{1} - tan {θ}_{2} )}^{2}} ] d θ = b [ \frac{sin {θ}_{1} cos {θ}_{1} - sin {θ}_{2} cos {θ}_{2}}{{( sin {θ}_{1} cos {θ}_{2} - sin {θ}_{2} cos {θ}_{1} )}^{2}} ] d θ = b [ \frac{cos ( {θ}_{1} + {θ}_{2} )}{sin ( {θ}_{1} - {θ}_{2} )} ] d θ , \\ dy = b \frac{tan {{θ}_{2} ( tan {θ}_{1} )}^{′} d θ + tan {{θ}_{1} ( tan {θ}_{2} )}^{′} d θ}{tan {θ}_{1} - tan {θ}_{2}} + b tan {θ}_{1} tan {θ}_{2} [ \frac{{( tan {θ}_{1} )}^{′} d θ - {( tan {θ}_{2} )}^{′} d θ}{- {( tan {θ}_{1} - tan {θ}_{2} )}^{2}} ] = b [ \frac{{tan}^{2} {{θ}_{1} ( tan {θ}_{2} )}^{′} - {tan}^{2} {{θ}_{2} ( tan {θ}_{1} )}^{′}}{{( tan {θ}_{1} - tan {θ}_{2} )}^{2}} ] d θ = b [ \frac{{sin}^{2} {θ}_{1} - {sin}^{2} {θ}_{2}}{{( sin {θ}_{1} cos {θ}_{2} - sin {θ}_{2} cos {θ}_{1} )}^{2}} ] d θ = b [ \frac{sin ( {θ}_{1} + {θ}_{2} )}{sin ( {θ}_{1} - {θ}_{2} )} ] d θ , \\ and \\ dz = dx tan {θ}_{3} + x {sec}^{2} {θ}_{3} d θ$$

Theoretical analysis shows that dx, dy, and dz are all positively correlated with dθ, dx is positively correlated with b, and dy and dz are negatively correlated with b. Positioning errors are closely related to position of S.

### Principle of Three-Dimensional Light-Field Detection

Two azimuth detectors arranged perpendicular to each other can perform 3D omnidirectional light-field detection. In spherical coordinates, for a beam incident from any direction (θ, φ), detector 1 detects the angle a1 between the projection of the beam onto the YOZ plane and the Z axis, while detector 2 detects the angle a2 between the projection of the beam onto the XOZ plane and the Z axis. The relationships between a1, a2 and θ, φ are as follows:

$$\begin{matrix}{α}_{1} = arctan ( \frac{y}{z} ) = arctan ( \frac{r sin θ sin φ}{r cos θ} ) \\ = arctan ( tan θ sin φ )\end{matrix} \\ \begin{matrix}{α}_{2} = arctan ( \frac{y}{z} ) = arctan ( \frac{r sin θ cos φ}{r cos θ} ) \\ = arctan ( tan θ cos φ )\end{matrix}$$

where a1 and a2 are encoded for the color output of detectors 1 and 2, respectively. In a specific experiment, a1 and a2 are obtained from the CIE tristimulus value of the color output of detectors 1 and 2, respectively. The azimuth angle φ and elevation angle θ of the beam are then obtained from the following expressions derived from equations:

$$θ = arctan ( \sqrt{{tan}^{2} {α}_{1} + {tan}^{2} {α}_{2} )} \\ φ = arctan ( \frac{tan {α}_{1}}{tan {α}_{2}} )$$

We further designed a 3D light-field image array using perovskite nanocrystals in which adjacent pixels are perpendicular to each other. For simplicity, the angle detected by detectors parallel to the x-axis is denoted by a_{i,j} (i and j refer to the rows and columns of the nanocrystal arrays), and the angle detected by detectors parallel to the y-axis is denoted by β_{i,j}. Each of the two azimuth detectors, which are perpendicular to each other, can reconstruct the angle of the beam incident at the center of the two pixels. For example, a1,1 and β1,2 can be used to calculate the 3D angle of the beam incident at point s11, whereas β2,1 and a1,1 can be used to calculate the 3D angle of the beam incident at point s21.

### Geometric Model of the 3D Imaging System

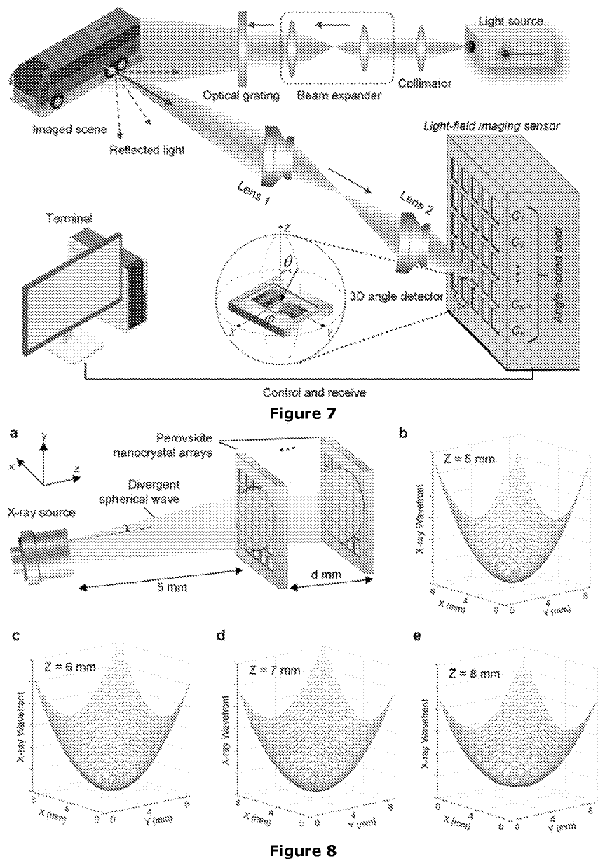

The 3D imaging scheme used was the triangulation method based on multiline structured light illumination. For simplicity, we first analyzed the situation under single-line structured light illumination (FIG. 9). To increase the change of the incident angle on the detector with distance changes and reduce the lateral movement of the light spot on the detector, we designed an objective composed of two lenses. L1 and L2 are the center points of lens 1 and lens 2, respectively. The light source at point O emits a single-line structured light perpendicular to the XOZ plane, and the distance between the points O and L1 is D. For each object point P (x, y, z) irradiated by the single-line structured light, its image by lens 1 in the X0Y0Z0O0 coordinate system of lens 2 is located at point P0 in the X0O0Y0 plane. The X0O0Z0 plane and the XOZ plane are coplanar. The angle between the ray OP and the XOZ plane is φ, and the angle between the projection OP′ of ray OP onto the XOZ plane and the OX axis is a. The angle between the optical axis O0Z0 of lens 1 and OL1 is βz. The angle between the projection P′L1 of ray PL1 onto the X0O0Z0 plane and the optical axis O0Z0 is β0, and the angle between the projection PzL1 of the ray PL1 onto the Y0O0Z0 plane and the optical axis O0Z0 is θ0. The projections of coordinate system of the lens 1 onto the XOZ plane and the Y0O0Z0 plane are shown in FIGS. 9b and 9c. The light L1P0 is refracted by lens 2 onto the detector plane X1O1Y1. The projection of the camera's coordinate system onto the XOZ plane and the Y0O0Z0 plane are shown in FIGS. 9d and 9e, respectively. The angle between the projection of ray P0P1 onto the X1O1Z1 plane and the optical axis O0Z0 is β1, and the angle between the projection of the ray P0P1 onto the Y1O1Z1 plane and the optical axis O1Z0 is θ1. The distance between lens 1 and lens 2 is d, and the distance between lens 2 and the detector plane is l. n and m represent the number of pixels on the detector in the X and Y directions, respectively.

According to the geometric relations in FIG. 9, the position coordinates x, y, z of the object point P can be solved:

$$z = \frac{D}{cot α + cot ( {β}_{t} - {β}_{0} )} \\ x = z cot α \\ y = \frac{z}{sin ( {β}_{t} - {β}_{0} )} cos {β}_{0} tan {θ}_{0} \\ tan {β}_{0} = ( l tan {β}_{1} - ns ) / d \\ tan {θ}_{0} = ( l tan {θ}_{1} - {ms}_{1} ) / d$$

where s and s1 represent the dimensions of a single pixel of the detector in the X and Y directions, respectively.

In a specific experiment, a, βz, D, d, and l need to be calibrated in advance. β1 and θ1 are obtained from the color output of angle detection, and then the coordinates x, y, z of object P are solved by formulae.

### Parameter Selection of the 3D Imaging System.

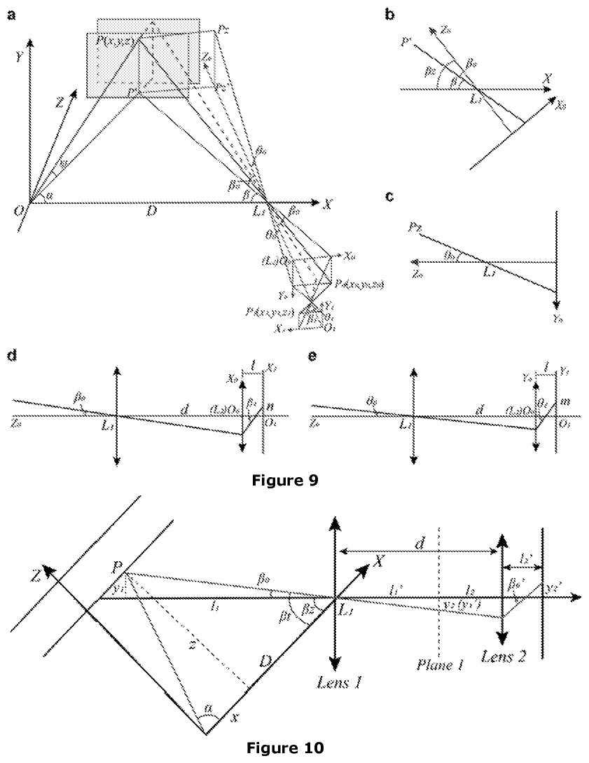

In the 2D scheme of the designed imaging system in FIG. 10, at a certain distance z, the lateral position x and the angle βt between the reflected or scattered light ray PL1 and the X axis are:

$$x = z cot ( α ) \\ {β}_{t} = arctan [ z / ( D - x ) ]$$

According to the geometric relationship in FIG. 10 and the Gaussian formula in geometric optics, the object distance l1 and the image distance l1′ of lens 1 are:

$${l}_{1} = - \frac{z}{sin {β}_{t}} cos ( {β}_{t} - {β}_{s} ) \\ \frac{1}{{l}_{1}^{′}} - \frac{1}{{l}_{1}} = \frac{1}{{f}_{1}} ⟹ {l}_{1}^{′} = \frac{{f}_{1} {l}_{1}}{{l}_{1} + {f}_{1}}$$

where f1 is the focal length of lens 1 and βz is the angle between the optical axis of lens 1 and the coordinate axis OX.

The object distance l2 and the image distance l2′ of lens 2 are:

$${l}_{2} = {l}_{1}^{′} - d , and {l}_{2}^{′} = \frac{{f}_{2} {l}_{2}}{{l}_{2} + {f}_{2}}$$

where f2 is the focal length of lens 2.

The vertical magnifications of lens 1 (β1), lens 2 (β2), and the combined system (B) are:

$${β}_{1} = \frac{{l}_{1}^{′}}{{l}_{1}} = \frac{{f}_{1}}{{l}_{1} + {f}_{1}} , {β}_{2} = \frac{{f}_{2}}{{l}_{2} + {f}_{2}} , and β = {β}_{1} {β}_{2} = \frac{{f}_{1} {f}_{2}}{{f}_{1} {l}_{1} - ( {l}_{1} + {f}_{1} ) ( d - {f}_{2} )}$$

Therefore, the height of images on the primary imaging plane and the detector imaging plane are:

$${y}_{1}^{′} = {y}_{1} {β}_{1} , and {y}_{2}^{′} = {y}_{1} β$$

where yₗ=−lₗ tan (β₁−β₂).

The angle between the light beam incident onto the primary image plane and the optical axis is:

$${β}_{0} = {β}_{1} - {β}_{2}$$

The angle between the light beam incident onto the detector imaging plane and the optical axis is:

$${β}_{0}^{′} = arctan [ \frac{d tan ( {β}_{0} ) + {y}_{2}^{′}}{{l}_{2}^{′}} ]$$

The goal of parameter optimization is to minimize the change of y2′ with distance z and the maximum change of β0′ with z. Therefore, we analyzed the relationship between δy2′/δz and δβ0′/δz and the system parameters D, a, βz, d, f1 and f2. Considering the resolution and the detectable range of distance, we set the system parameters as D=50 mm, a=90°, βz=78°, f1=75 mm, f2=25 mm, and d=145 mm. Optimal imaging parameters are listed in Table 1.

TABLE 1
Optimal parameters for imaging 500 mm distance range

| Imaging | β₀ | β′₀ | y′₁ | y′₂ |
|---|---|---|---|---|
| parameter | (degree) | (degree) | (mm) | (mm) |
| z = 500 mm | 6.2894 | 28.5180 | −9.7266 | 6.9476 |
| z = 500.1 mm | 6.2905 | 28.5218 | −9.728 | 6.9486 |
| z = 700 mm | 7.9144 | 33.5093 | −11.6873 | 8.3481 |

When the distance z is changed by 0.1 mm, the angle β0′ of the light incident on the detector changes by approximately 0.0038°, and the light spot moves on the detector by approximately 1 μm, which is indistinguishable for a conventional CCD with a pixel size of 3-10 μm. By attaching the light-field imaging film onto the CCD, the distance change of 0.1 mm can be differentiated by angle detection. Under optimized system parameters, a distance change of 200 mm causes the spot on the detector to move by 1.4 mm. It should be noted that the selection of imaging parameters depends largely on the distance z, so the system parameters must be determined according to the distance range of the application.

### Calibration of the 3D Imaging System

### Calibration of the Emission Angle of Multiline Structured Light

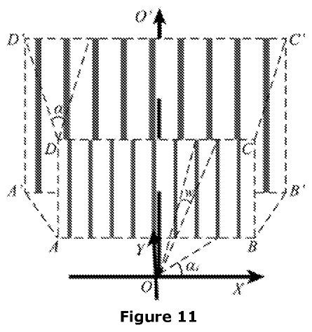

The system uses an optical grating after a light source to generate multiline structured light and scans the object surface in a normal incidence mode. The angle between the two edge light planes of the structured light is a, the angle between each structured light plane and the XOY plane is ai, and the angle between the structured light planes is w (FIG. 11). Since the structured light is incident perpendicular to the target, ai can be obtained by the following formula:

$${α}_{1} = 90 ° \pm nw$$

Where n represents the number of the line-structured light plane.

In the actual calibration, the structured light was vertically incident on a white flat plate, OO′ is the optical axis of the light source, and points A, B, C, and D were the four corner points of the edge light strip on the surface. Points A′, B′, C′, and D′ are the four corner points of the edge light strip after the flat plate moves a certain distance. The coordinates of A, B, C, D, A′, B′, C′, and D′ are measured, and the plane equations of plane AA′D′D and plane BCC′B′ can be established in the Cartesian coordinate system:

$${a}_{1} x + {b}_{1} y + {c}_{1} z + {d}_{1} = 0 \\ {a}_{2} x + {b}_{2} y + {c}_{2} z + {d}_{2} = 0$$

Then the angle a between the two edge light planes of the structured light is:

$$cos α = \frac{\vert {a}_{1} {a}_{2} + {b}_{1} {b}_{2} + {c}_{1} {c}_{2} \vert}{\sqrt{{a}_{1}^{2} + {b}_{1}^{2} + {c}_{1}^{2}} \sqrt{{a}_{2}^{2} + {b}_{2}^{2} + {c}_{2}^{2}}}$$

### Calibration of Homemade Camera Parameters

The conversion formula of the world coordinate system (xw, yw, zw) and the pixel coordinate system (u, v) of the CCD is:

$$s [ \begin{matrix}u \\ v \\ 1\end{matrix} ] = {K}_{3 * 3} [ \begin{matrix}R & T \\ 0 & 1\end{matrix} ] [ \begin{matrix}{x}_{w} \\ {y}_{w} \\ {z}_{w} \\ 1\end{matrix} ]$$

Where s is the scale factor, K is the internal parameter matrix of the camera, R is the rotation matrix of the camera in the world coordinate system, and T is the translation matrix. The Zhang calibration method was used to determine internal parameters, external parameters, and distortion parameters of the camera. First, we printed a piece of paper with a black and white grid, and then took several images of the paper from different angles with the camera to be calibrated. Further, the camera calibration library toolbox_calib of Matlab was used to identify and process the feature points in the collected images to obtain the internal and external parameters as well as the distortion parameters of the camera.

### Wavefront Detection Principle

Wavefront detection for extreme ultraviolet (EUV) light or X-rays typically uses Hartmann (e.g., Shack-Hartmann) wavefront sensing techniques in which a beam passes through a hole array (e.g., microlens array) and is projected onto a CCD camera that detects the beam sampled from each hole (e.g., microlens). The positions of individual point centroids are then measured and compared with reference positions. This enables the wavefront's local slopes to be measured at a large number of points by the following formula:

$$tan {θ}_{ij}^{x} = \frac{Δ {x}_{ij}}{L} , tan {θ}_{ij}^{y} = \frac{Δ {y}_{ij}}{L}$$

In our light-field sensor-based wavefront measurements, the local slope of the wavefront is directly obtained by the angle detectors without the need for an array of apertures or microlenses.

The wavefront's local slopes can be written according to the following expressions:

$$\{ \begin{matrix}tan {θ}_{ij}^{x} = \frac{dW ( {x}_{ij}^{0} , {y}_{ij}^{0} )}{dx} = \frac{λ}{2 π} \frac{d φ ( {x}_{ij}^{0} , {y}_{ij}^{0} )}{dx} \\ tan {θ}_{ij}^{y} = \frac{dW ( {x}_{ij}^{0} , {y}_{ij}^{0} )}{dy} = \frac{λ}{2 π} \frac{d φ ( {x}_{ij}^{0} , {y}_{ij}^{0} )}{dy}\end{matrix}$$

where W (x, y) represents the optical path difference and φ (x, y) is the spatial phase. Integration of the measured derivative function enables reconstruction of the incident beam wavefront.

It will be appreciated that many further modifications and permutations of various aspects of the described embodiments are possible. Accordingly, the described aspects are intended to embrace all such alterations, modifications, and variations that fall within the spirit and scope of the appended claims.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

Throughout this specification and the claims which follow, unless the context requires otherwise, the phrase “consisting essentially of”, and variations such as “consists essentially of” will be understood to indicate that the recited element(s) is/are essential i.e. necessary elements of the invention. The phrase allows for the presence of other non-recited elements which do not materially affect the characteristics of the invention but excludes additional unspecified elements which would affect the basic and novel characteristics of the method defined.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

1. A light field detector for converting a vector of an electromagnetic radiation into a chromatic output, comprising at least one azimuth detector on a transparent substrate and the at least one azimuth detector comprising at least two luminescent nanocrystal pixels having different emission wavelengths relative to each other.

2. The light field detector according to claim 1, comprising at least two said azimuth detectors oriented perpendicularly to each other.

3. The light field detector according to claim 1, comprising at least three azimuth detectors, the at least three azimuth detectors configured to cooperate to convert the vector of electromagnetic radiation into a CIE XYZ tristimulus value.

4. The light field detector according to claim 1, comprising at least three azimuth detectors, wherein the at least three azimuth detectors are oriented such that a first and second azimuth detector are parallel to each other and a third azimuth detector is substantially perpendicular to the first and second azimuth detector.

5. The light field detector according to claim 1, wherein the at least two luminescent nanocrystal pixels are parallel to each other; or
wherein the at least two luminescent nanocrystal pixels is three luminescent nanocrystal pixels, wherein three luminescent nanocrystal pixels are stacked such that they form a semi-cylindrical configuration or a rectangular pyramidal configuration.

6. The light field detector according to claim 1, wherein the emission wavelengths correspond to colours red, green, or blue.

7. (canceled)

8. (canceled)

9. The light field detector according to claim 1, wherein the luminescent nanocrystals pixels comprises perovskite nanocrystals, ZnS:Cu²⁺/Mn²⁺, SrAl₂O₄:Eu²⁺/Dy³⁺ phosphors, upconversion nanoparticles, black phosphorus, or a combination thereof.

10. The light field detector according to claim 9, wherein the perovskite nanocrystal is CsPbX₃, wherein X is selected from Cl, Br and/or I, wherein the perovskite nanocrystals are characterised by an emission wavelength of about 445 nm, about 523 nm, or about 652 nm.

11. (canceled)

12. The light field detector according to claim 1, wherein each azimuth detector is characterised by a size of about 1×1 μm² to about 200×200 μm².

13. The light field detector according to claim 1, wherein the 3D light field detector is characterised by an angular change detection limit of less than 0.015° and/or an azimuth detector density of about 80 azimuth detectors per mm² to about 200 azimuth detectors per mm².

14. (canceled)

15. The light field detector according to claim 1, wherein the transparent substrate is a polymer substrate, or preferably PDMS.

16. The light field detector according to claim 1, wherein the electromagnetic radiation has a wavelength of about 0.002 nm to about 500 nm.

17. A light field sensor, comprising:
a) a light field detector according to claim 1; and
b) a colour charge-coupled device (CCD) electromagnetically coupled to the light field detector for converting the chromatic output into an electric signal.

18. The light field sensor according to claim 17, further comprising a computer system configured to convert the electric signal into a spatial coordinate in a three-dimensional Cartesian coordinate system.

19. The light field sensor according to claim 17, wherein the sensor is characterised by an accuracy of about 0.5 mm at a distance of about 0.5 m and/or a spatial sampling density of about 300 points/mm² to about 600 points/mm².

20. (canceled)

21. A method of fabricating a light field detector, comprising:
a) forming or positioning at least one azimuth detector on a transparent substrate, wherein each azimuth detector comprises at least two luminescent nanocrystal pixels having different emission wavelengths relative to each other.

22. The method according to claim 21, wherein the step of forming or positioning at least one azimuth detector comprises lithographically patterning the at least two luminescent nanocrystal pixels in a silicon template and curing a polymer over the at least two luminescent nanocrystal pixels in order to form the transparent substrate.

23. The method according to claim 21, wherein the step of forming or positioning at least one azimuth detector further comprises lithographically patterning a third luminescent nanocrystal pixel in another silicon template and adhering it to the transparent substrate patterned with the at least two luminescent nanocrystal pixels.

24. The method according to claim 21, wherein each of the at least two luminescent nanocrystal pixels comprises nanocrystals dispersed in a polymer matrix; wherein the at least two luminescent nanocrystal pixels is each independently characterised by a nanocrystal density of about 0.001 mol/mL to about 0.01 mol/mL.

25. (canceled)

26. The method according to claim 21, wherein a) forming or positioning at least one azimuth detector on a transparent substrate comprises arraying a plurality of azimuth detectors on a transparent substrate such that each azimuth detector is oriented perpendicularly to a neighbouring azimuth detector,
wherein each azimuth detector comprises at least two luminescent nanocrystal pixels having different emission wavelengths relative to each other.
